(19) United States
(12) Patent Application Publication
(10) Pub. No.: US 2009/0027943 A1
(43) Pub. Date: Jan. 29, 2009

(54) RESISTIVE MEMORY INCLUDING BIDIRECTIONAL WRITE OPERATION

(76) Inventors: Thomas Nirschl, Essex Junction, VT (US); Mark Lamorey, South Burlington, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/782,312

(22) Filed: Jul. 24, 2007

(51) Int. Cl. G11C 11/00

(52) U.S. Cl. 365/148; 365/163

(57) ABSTRACT

A memory includes a first electrode, a second electrode, and a resistive memory element coupled between the first electrode and the second electrode. The memory includes a circuit configured to write a data value to the resistive memory element by sequentially applying a first signal from the first electrode to the second electrode and a second signal from the second electrode to the first electrode.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity. In addition, the amorphous and crystalline states may be mixed within the memory element.

Phase changes in the phase change materials may be induced reversibly. In this way, the memory may change from the amorphous state to the crystalline state and from the crystalline state to the amorphous state in response to temperature changes. The temperature changes to the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The level of current and/or voltage generally corresponds to the temperature induced within the phase change material in each memory cell.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. For simplicity, the description in this disclosure is substantially focused on four different resistance levels or states and two bits of data per cell. This is for illustrative purposes only, however, and not intended to limit the scope of the invention. In principle it is possible to store three or more states.

To program a phase change memory cell to an intermediate resistance value, the amount of crystalline material coexisting with amorphous material and hence the cell resistance is controlled via a suitable write strategy. The amount of crystalline material coexisting with amorphous material should be precisely controlled to ensure consistent resistance values for multi-bit storage. Consistent resistance values having a narrow distribution of the different resistance levels ensure that a sufficient sensing margin can be obtained.

For these and other reasons, there is a need for the present invention.

### SUMMARY

One embodiment provides a memory. The memory includes a first electrode, a second electrode, and a resistive memory element coupled between the first electrode and the second electrode. The memory includes a circuit configured to write a data value to the resistive memory element by sequentially applying a first signal from the first electrode to the second electrode and a second signal from the second electrode to the first electrode.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a memory device.

FIG. 2 is a diagram illustrating one embodiment of a memory element in four different states.

FIG. 3 is a signal diagram illustrating one embodiment of bit line signals for a write operation.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

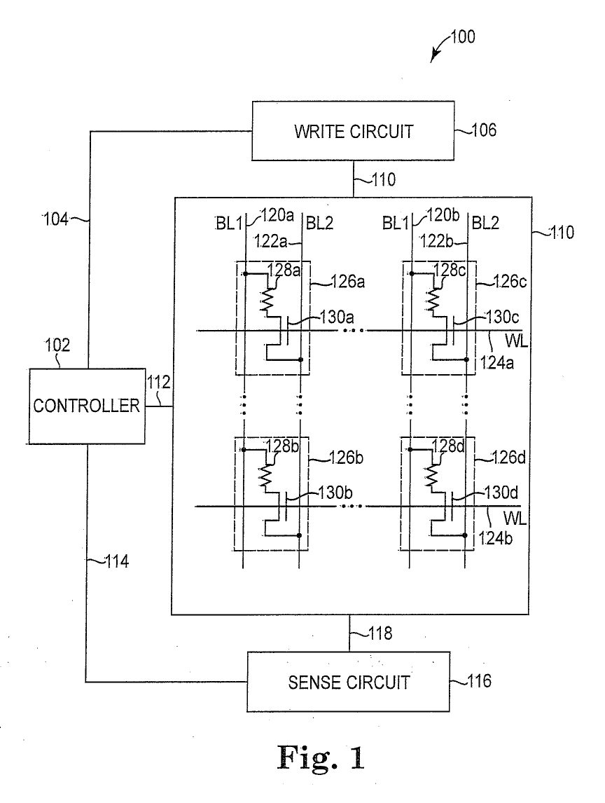

FIG. 1 is a diagram illustrating one embodiment of a memory device 100. Memory device 100 includes a controller 102, a write circuit 106, a memory array 110, and a sense circuit 116. Memory array 110 includes a plurality of phase change memory cells 126a-126d (collectively referred to as phase change memory cells 126), a plurality of first bit lines (BL1s) 120a-120b (collectively referred to as first bit lines 120), a plurality of second bit lines (BL2s) 122a-122b (collectively referred to as second bit lines 122), and a plurality of word lines (WLs) 124a-124b (collectively referred to as word lines 124).

Each of phase change memory cells 126a-126d stores data based on the amorphous and crystalline states of phase change material in the memory cell. Also, each of the memory cells 126a-126d can be programmed into two or more states by programming the phase change material to have intermediate resistance values. To program one of the memory cells 126a-126d, at least one first voltage and/or current pulse is applied to one side of the selected memory cell 126a-126d and at least one second voltage and/or current pulse is applied to the other side of the selected memory cell 126a-126d after the first voltage and/or current pulse. In this way, current passes through the selected memory cell 126a-126d in a first direction in response to the first voltage and/or current pulse and through the selected memory cell 126a-126d in a second direction opposite the first direction in response to the second voltage and/or current pulse. By alternating the direction of the current through the selected memory cell 126a-126d during a write operation, the homogeneity of the phase change material is improved.

As used herein, the term “electrically coupled” is not meant to mean that the elements must be directly coupled together and intervening elements may be provided between the “electrically coupled” elements.

Controller 102 is electrically coupled to write circuit 106 through signal path 104, to memory array 110 through signal path 112, and to sense circuit 116 through signal path 114. Write circuit 106 is electrically coupled to memory array 110 though signal path 108. Memory array 110 is electrically coupled to sense circuit 116 through signal path 118.

Each phase change memory cell 126 is electrically coupled to a first bit line 120, a second bit line 122, and a word line 124. Phase change memory cell 126a is electrically coupled to first bit line 120a, second bit line 122a, and word line 124a. Phase change memory cell 126b is electrically coupled to first bit line 120a, second bit line 122a, and word line 124b. Phase change memory cell 126c is electrically coupled to first bit line 120b, second bit line 122b, and word line 124a. Phase change memory cell 126d is electrically coupled to first bit line 120b, second bit line 122b, and word line 124b.

Each phase change memory cell 126 includes at least one phase change element 128 and at least one transistor 130. While transistor 130 is a field-effect transistor (FET) in the illustrated embodiment, in other embodiments, transistor 130 can be other suitable devices such as a bipolar transistor or a 3D transistor structure. In another embodiment, each phase change element 128 is electrically coupled to more than one select device. Phase change memory cell 126a includes phase change element 128a and transistor 130a. One side of phase change element 128a is electrically coupled to first bit line 120a, and the other side of phase change element 128a is electrically coupled to one side of the source-drain path of transistor 130a. The other side of the source-drain path of transistor 130a is electrically coupled to second bit line 122a. The gate of transistor 130a is electrically coupled to word line 124a.

Phase change memory cell 126b includes phase change element 128b and transistor 130b. One side of phase change element 128b is electrically coupled to first bit line 120a, and the other side of phase change element 128b is electrically coupled to one side of the source-drain path of transistor 130b. The other side of the source-drain path of transistor 130b is electrically coupled to second bit line 122a. The gate of transistor 130b is electrically coupled to word line 124b.

Phase change memory cell 126c includes phase change element 128c and transistor 130c. One side of phase change element 128c is electrically coupled to first bit line 120b, and the other side of phase change element 128c is electrically coupled to one side of the source-drain path of transistor 130c. The other side of the source-drain path of transistor 130c is electrically coupled to second bit line 122b. The gate of transistor 130c is electrically coupled to word line 124a.

Phase change memory cell 126d includes phase change element 128d and transistor 130d. One side of phase change element 128d is electrically coupled to first bit line 120b, and the other side of phase change element 128d is electrically coupled to one side of the source-drain path of transistor 130d. The other side of the source-drain path of transistor 130d is electrically coupled to second bit line 122b. The gate of transistor 130d is electrically coupled to word line 124b.

Each phase change element 126 may be changed from an amorphous state to a crystalline state or from a crystalline state to an amorphous state under the influence of temperature change. The amount of crystalline material coexisting with amorphous material in the phase change material of one of the phase change elements 128a-128d thereby defines two or more states for storing data within memory device 100.

In the amorphous state, a phase change material exhibits significantly higher resistivity than in the crystalline state. Therefore, the two or more states of phase change elements 128a-128d differ in their electrical resistivity. In one embodiment, the two or more states include two states and a binary system is used, wherein the two states are assigned bit values of “0” and “1”. In another embodiment, the two or more states are three states and a ternary system is used, wherein the three states are assigned bit values of “0”, “1”, and “2”. In another embodiment, the two or more states are four states that are assigned multi-bit values, such as “00”, “01”, “10”, and “11”. In other embodiments, the two or more states can be any suitable number of states in the phase change material of a phase change element.

Controller 102 includes a microprocessor, microcontroller, or other suitable logic circuitry for controlling the operation of memory device 100. Controller 102 controls read and write operations of memory device 100 including the application of control and data signals to memory array 110 through write circuit 106 and sense circuit 116.

In one embodiment, write circuit 106 provides voltage pulses through signal path 108, first bit lines 120, and second bit lines 122 to memory cells 126 to program the memory cells. In other embodiments, write circuit 106 provides current pulses through signal path 108, first bit lines 120, and second bit lines 122 to memory cells 126 to program the memory cells. Write circuit 106 alternates the direction of the voltage or current pulses through memory cells 126 during a write operation.

During a set operation of phase change memory cell 126a, a first set current or voltage pulse is selectively enabled by write circuit 106 and sent through one of first bit line 120a and second bit line 122a to phase change element 128a thereby heating phase change element 128a above its crystallization temperature (but usually below its melting temperature) with word line 124a selected to activate transistor 130a. Next, a second set current or voltage pulse is selectively enabled by write circuit 106 and sent through the other one of first bit line 120a and second bit line 122a to phase change element 128a thereby continuing to heat phase change element 128a above its crystallization temperature. In one embodiment, additional current or voltage pulses are selectively enabled by write circuit 106 and sequentially sent through first bit line 120a and second bit line 122a to phase change element 128a. In this way, phase change element 128a reaches its crystalline state or a partially crystalline and partially amorphous state during this set operation.

During a reset operation of phase change memory cell 126a, a first reset current or voltage pulse is selectively enabled by write circuit 106 and sent through one of first bit line 120a and second bit line 122a to phase change element 128a. The reset current or voltage quickly heats phase change element 128a above its melting temperature. Next, a second reset current or voltage pulse is selectively enabled by write circuit 106 and sent through the other of first bit line 120a and second bit line 122a to phase change element 128a thereby continuing to heat phase change element 128a above its melting temperature. In one embodiment, additional current or voltage pulses are selectively enabled by write circuit 106 and sequentially sent through first bit line 120a and second bit line 122a to phase change element 128a. After the current or voltage pulses are turned off, phase change element 128a quickly quench cools into the amorphous state or a partially amorphous and partially crystalline state. Phase change memory cells 126b-126d and other phase change memory cells 126 in memory array 110 are set and reset similarly to phase change memory cell 126a using similar sequentially applied current or voltage pulses, which alternate directions through each phase change memory cell.

Sense circuit 116 reads each of the two or more states of memory cells 126 through first bit lines 120, second bit lines 122, and signal path 118. In one embodiment, to read the resistance of one of the memory cells 126, sense circuit 116 provides current that flows through one of the memory cells 126. Sense circuit 116 then reads the voltage across that one of the memory cells 126. In another embodiment, sense circuit 116 provides voltage across one of the memory cells 126 and reads the current that flows through that one of the memory cells 126. In another embodiment, write circuit 106 provides voltage across one of the memory cells 126 and sense circuit 116 reads the current that flows through that one of the memory cells 126. In another embodiment, write circuit 106 provides current that flows through one of the memory cells 126 and sense circuit 116 reads the voltage across that one of the memory cells 126.

In one embodiment, the current used to sense the state of a memory cell flows from a first bit line 120 through a selected memory cell 126 to a second bit line 122. In another embodiment, the current used to sense the state of a memory cell flows from a second bit line 122 through a selected memory cell 126 to a first bit line 120. In this embodiment, unselected memory cells experience minimal read disturb in response to read pulses or ramps. Read disturb has the potential to modify the resistance state of unselected memory cells if the disturbance is too large.

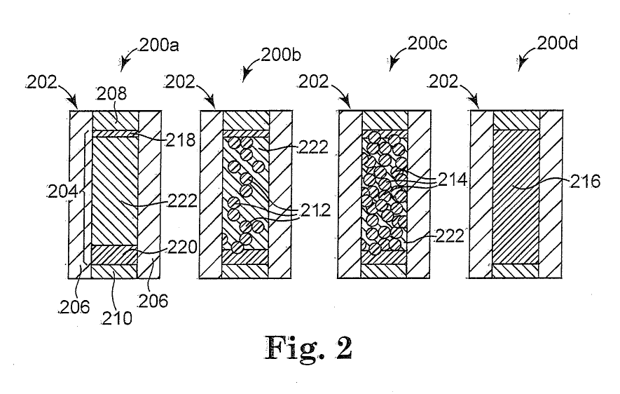

FIG. 2 is a diagram illustrating one embodiment of a phase change element 202 in four different states at 200a, 200b, 200c, and 200d. Phase change element 202 includes a phase change material 204 that is laterally surrounded by insulation material 206. In other embodiments, phase change element 202 can have any suitable geometry including phase change material 204 in any suitable geometry and insulation material 206 in any suitable geometry.

Phase change material 204 is electrically coupled at one end to a first electrode 208 and at the other end to a second electrode 210. Pulses are provided to phase change element 202 via first electrode 208 and second electrode 210. During a write operation, the current path through phase change material 204 alternates from first electrode 208 to second electrode 210 and from second electrode 210 to first electrode 208. In one embodiment, each of the phase change elements 128a-128d is similar to phase change element 202. Phase change element 202 provides a storage location for storing bits of data.

Insulation material 206 can be any suitable insulator, such as SiO₂, SiOₓ, SiN, fluorinated silica glass (FSG), boro-phosphorous silicate glass (BPSG), boro-silicate glass (BSG), or low-k material. First electrode 208 and second electrode 210 can be any suitable electrode material, such as TiN, TaN, W, Al, Ti, Ta, TiSiN, TaSiN, TiAlN, TaAlN, or Cu.

Phase change material 204 may be made up of a variety of materials in accordance with the present invention. Generally, chalcogenide alloys that contain one or more elements from group VI of the periodic table are useful as such materials. In one embodiment, phase change material 204 of phase change element 202 is made up of a chalcogenide compound material, such as GeSbTe, SbTe, GeTe, or AgInSbTe. In another embodiment, phase change material 204 is chalcogen free, such as GeSb, GaSb, InSb, or GeGaInSb. In other embodiments, phase change material 204 is made up of any suitable material including one or more of the elements Ge, Sb, Te, Ga, As, In, Se, and S.

Phase change material 204 is programmed into one of four states to store two bits of data. A selection device, such as a transistor 130, is electrically coupled to first electrode 208 to control the application of pulses to phase change material 204. The pulses reset phase change material 204 and program one of the other three states into phase change material 204. At 200b, a small fraction 212 of phase change material 204 has been programmed to change the resistance through phase change material 204 and phase change element 202. At 200c, a medium sized fraction 214 of phase change material 204 has been programmed to change the resistance through phase change material 204 and phase change element 202. At 200d, a large fraction 216, which is substantially all of phase change material 204, has been programmed to change the resistance through phase change material 204 and phase change element 202.

The size of the programmed fraction is related to the resistance through phase change material 204 and phase change element 202. The three different phase change fractions at 200b-200d plus the initial state at 200a provide four states in phase change material 204, and phase change element 202 provides a storage location for storing two bits of data. In one embodiment, the state of phase change element 202 at 200a is a “00”, the state of phase change element 202 at 200b is a “01”, the state of phase change element 202 at 200c is a “10”, and the state of phase change element 202 at 200d is a “11”.

At 200a, phase change material 204 is reset to a substantially amorphous state. During a reset operation of phase change element 202, at least two reset pulses are selectively enabled by the selection device and sequentially sent from first electrode 208 through phase change material 204 to second electrode 210 and from second electrode 210 through phase change material 204 to first electrode 208. Therefore, the sequential reset pulses are applied to phase change material 204 from opposite directions. The reset pulses heat phase change material 204 above its melting temperature and phase change material 204 is quickly cooled to achieve the substantially amorphous state at 200a. After a reset operation, phase change material 204 includes crystalline state phase change material at 218 and 220, and amorphous state phase change material at 222. The substantially amorphous state at 200a is the highest resistance state of phase change element 202.

To program phase change material 204 into one of the other three states 200b-200d, at least two set pulses are sequentially applied to phase change material 204 in alternating directions via a write circuit, such as write circuit 106. At 200b, the set pulses are provided to program the small volume fraction 212 into a crystalline state. The crystalline state is less resistive than the amorphous state and phase change element 202 at 200b has a lower resistance than phase change element 202 in the substantially amorphous state at 200a. The partially crystalline and partially amorphous state at 200b is the second highest resistance state of phase change element 202.

At 200c, at least two set pulses are sequentially applied to phase change material 204 in alternating directions to program the medium volume fraction 214 into a crystalline state. Since the crystalline fraction 214 is larger than the crystalline faction 212 and the crystalline state is less resistive than the amorphous state, phase change element 202 at 200c has a lower resistance than phase change element 202 at 200b and phase change element 202 in the amorphous state at 200a. The partially crystalline and partially amorphous state at 200c is the second lowest resistance state of phase change element 202.

At 200d, at least two set pulses are sequentially applied to phase change material 204 in alternating directions to program substantially all of the phase change material 216 into the crystalline state. Since the crystalline state is less resistive than the amorphous state, phase change element 202 at 200d has a lower resistance than phase change element 202 at 200c, phase change element 202 at 200b, and phase change element 202 in the amorphous state at 200a. The substantially crystalline state at 200d is the lowest resistance state of phase change element 202. In other embodiments, phase change element 202 can be programmed into any suitable number of resistance values or states. In other embodiments, phase change element 202 can be set to a substantially crystalline state and reset pulses can be used to program phase change element 202 to the desired resistance value or state.

By alternating the direction of the set or reset pulses applied to phase change element 202, the homogeneity of phase change material 204 in each of the four states at 200a-200d is improved. The improved homogeneity provides consistent resistance values having a narrow distribution of the different resistance levels. The narrow distribution of the different resistance levels ensures that a sufficient sensing margin can be obtained.

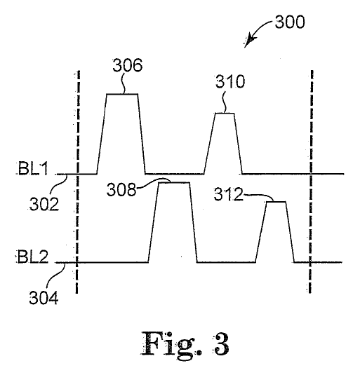

FIG. 3 is a signal diagram 300 illustrating one embodiment of bit line signals for a write operation. Signal diagram 300 includes BL1 signal 302 on a first bit line 120 and BL2 signal 304 on a second bit line 122. During a write operation of a selected memory cell 126, write circuit 106 provides a first write pulse 306 on BL1 signal 302. During first write pulse 306, the second bit line is coupled to a common or ground such that current flows through the selected memory cell 126 from the first bit line to the second bit line. Next, write circuit 106 provides a second write pulse 308 on BL2 signal 304. During second write pulse 308, the first bit line is coupled to the common or ground such that current flows through the selected memory cell 126 from the second bit line to the first bit line. In one embodiment, first write pulse 306 and second write pulse 308 have the same amplitude and/or duration. In other embodiments, first write pulse 306 and second write pulse 308 have different amplitudes and/or durations. In one embodiment, first write pulse 306 and second write pulse 308 are current pulses. In another embodiment, first write pulse 306 and second write pulse 308 are voltage pulses.

Next, write circuit 106 provides a third write pulse 310 on BL1 signal 302. In one embodiment, third write pulse 310 has a different amplitude and/or duration than second write pulse 308. In one embodiment, third write pulse 310 has a smaller amplitude and/or duration than second write pulse 308. During third write pulse 310, the second bit line is coupled to the common or ground such that current flows through the selected memory cell 126 from the first bit line to the second bit line. Next, write circuit 106 provides a fourth write pulse 312 on BL2 signal 304. During fourth write pulse 312, the first bit line is coupled to the common or ground such that current flows through the selected memory cell 126 from the second bit line to the first bit line. In one embodiment, third write pulse 310 and fourth write pulse 312 have the same amplitude and/or duration. In other embodiments, third write pulse 310 and fourth write pulse 312 have different amplitudes and/or durations. In one embodiment, additional write pulses are sequentially applied on BL1 signal 302 and BL2 signal 304 to program the selected memory cell 126.

In one embodiment, first write pulse 306, second write pulse 308, third write pulse 310, and fourth write pulse 312 are current pulses. In another embodiment, first write pulse 306, second write pulse 308, third write pulse 310, and fourth write pulse 312 are voltage pulses. While the write pulses illustrated in signal diagram 300 are substantially rectangular shaped, in other embodiments other suitable pulse shapes are used, such as triangular shaped pulses.

While the specific embodiments described herein substantially focused on using phase change memory elements, the present invention can be applied to any suitable type of resistive memory elements including unipolar memory elements, such as binary oxide resistive memory elements.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory comprising:
a first electrode;
a second electrode;
a resistive memory element coupled between the first electrode and the second electrode; and
a circuit configured to write a data value to the resistive memory element by sequentially applying a first signal from the first electrode to the second electrode and a second signal from the second electrode to the first electrode.

2. The memory of claim 1, wherein the resistive memory element comprises a phase change element.

3. The memory of claim 2, wherein the phase change element comprises a multi-bit phase change element.

4. The memory of claim 1, further comprising:
a transistor coupled to the first electrode for selectively accessing the resistive memory element.

5. The memory of claim 4, further comprising:
a first bit line coupled to the transistor; and
a second bit line coupled to the second electrode.

6. The memory of claim 4, wherein the circuit is configured to read the resistive memory element by applying a read signal through the transistor to the resistive memory element.

7. A memory comprising:
a first bit line;
a second bit line;
a resistive memory cell coupled between the first bit line and the second bit line; and
a circuit configured to write a data value to the resistive memory cell by sequentially applying a first signal from the first bit line to the second bit line and a second signal from the second bit line to the first bit line.

8. The memory of claim 7, wherein the resistive memory cell comprises a phase change memory cell.

9. The memory of claim 7, wherein the first signal comprises a first current signal and the second signal comprises a second current signal.

10. The memory of claim 7, further comprising:
an access device coupled between the resistive memory cell and the first bit line for selecting the resistive memory cell for access.

11. The memory of claim 10, wherein the circuit is configured to read the resistive memory cell by applying a read signal from the first bit line to the second bit line.

12. A memory comprising:
a phase change memory cell;
means for applying a first signal through the memory cell in a first direction during a first portion of a write operation to the memory cell; and
means for applying a second signal through the memory cell in a second direction during a second portion of the write operation to the memory cell.

13. The memory of claim 12, wherein an amplitude and duration of the first signal is substantially equal to an amplitude and duration of the second signal.

14. The memory of claim 12, wherein the first signal comprises a first current signal and the second signal comprises a second current signal.

15. The memory of claim 12, wherein the first signal comprises a first voltage signal and the second signal comprises a second voltage signal.

16. A method for accessing a memory, the method comprising:
applying a first signal through a resistive memory cell in a first direction to perform a first portion of a write operation to the memory cell; and
applying a second signal through the memory cell in a second direction to perform a second portion of the write operation to the memory cell.

17. The method of claim 16, further comprising:
applying a third signal through the memory cell in the first direction to perform a third portion of the write operation to the memory cell; and
applying a fourth signal through the memory cell in the second direction to perform a fourth portion of the write operation to the memory cell.

18. The method of claim 16, wherein applying the first signal through the memory cell comprises applying the first signal through a phase change memory cell.

19. The method of claim 16, wherein applying the first signal through the memory cell comprises applying the first signal through a multi-bit memory cell.

20. The method of claim 16, further comprising:
activating a selection device to access the resistive memory cell.

21. The method of claim 16, wherein applying the first signal comprises applying a first current signal, and wherein applying the second signal comprises applying a second current signal.

22. A method for accessing a memory, the method comprising:
providing a first pulse from a first bit line to a phase change element to perform a first portion of a write operation to the phase change element; and
providing a second pulse from a second bit line to the phase change element to perform a second portion of the write operation to the phase change element.

23. The method of claim 22, further comprising:
providing a third pulse from the first bit line to the phase change element to perform a third portion of the write operation to the phase change element; and
providing a fourth pulse from the second bit line to the phase change element to perform a fourth portion of the write operation to the phase change element.

24. The method of claim 22, wherein providing the second pulse to the phase change element comprises providing a second pulse having an amplitude and duration substantially equal to an amplitude and duration of the first pulse.

25. The method of claim 22, wherein providing the first pulse comprises providing a first current pulse, and wherein providing the second pulse comprises providing a second current pulse.

26. The method of claim 22, farther comprising:
activating a transistor coupled between the first bit line and the phase change element to access the phase change element.

27. The method of claim 26, farther comprising:
applying a read pulse from the first bit line through the phase change element to the second bit line to read a data value stored in the phase change element.
